(19) United States
(12) Patent Application Publication
(10) Pub. No.: US 2017/0268542 A1
(43) Pub. Date: Sep. 21, 2017

(54) REMOTE CONTROL WITH INTERCHANGEABLE CLIP SYSTEM FOR ATTACHING AN AUXILIARY REMOTE CONTROL

(71) Applicant: Brett Joseph Epstein, Jupiter, FL (US)

(72) Inventor: Brett Joseph Epstein, Jupiter, FL (US)

(21) Appl. No.: 15/462,563

(22) Filed: Mar. 17, 2017

Related U.S. Application Data
(60) Provisional application No. 62/310,804, filed on Mar. 20, 2016.

(51) Int. Cl. F16B 1/00; F16B 2/22; F16B 2/08; H05K 7/14

(52) U.S. Cl. CPC F16B 1/0014; H05K 7/14; F16B 2/22; F16B 2/08

(57) ABSTRACT

A system for securing two independent electronic device remote control units together. The system comprises one or more components, including an electronic device remote control and an interchangeable electronic device remote control securing member configured for attaching an auxiliary remote control device thereto. The system provides a mechanism to secure together at least two remote control devices that are not, or are not capable of, synchronizing each individual functionality into a single unit.

### REFERENCE TO RELATED APPLICATIONS

In accordance with 37 C.F.R. 1.76, a claim of priority is included in an Application Data Sheet filed concurrently herewith. Accordingly, the present invention claims priority under 35 U.S.C. §119(e), 120, 121, and/or 365(c) to U.S. Provisional Patent Application No. 62/310,804, entitled “Remote Control with Interchangeable Clip System for Attaching an Auxiliary Remote Control”, filed Mar. 20, 2016. The contents of the above referenced application are incorporated herein by reference in its entirety.

### FIELD OF THE INVENTION

The present invention relates to remote control of electronic equipment, to a system and device for controlling electronic equipment remotely; and more particularly, to a device or system that secures a plurality of independent, electronic remote devices.

### BACKGROUND OF THE INVENTION

Electronic devices are commonplace in most households. Most common of these electronic devices are entertainment units, such as televisions. Traditionally, viewers use a media delivery company, such as local or national cable companies, to view their programming. Such service requires some type of box with a control unit independent from a control unit that remotely controls the functioning of the television. External devices, such as Blue Ray or DVD players, allow users to view additional media while in the comfort of their own home. These devices also come with their own control unit independent from a control unit that remotely controls the functioning of the television. To enhance the viewing pleasure, it is not uncommon for consumers to connect audio receivers or speaker systems to their home televisions. These devices also come with their own control unit independent from a control unit that remotely controls the functioning of the television. Finally, streaming devices/media players, such as AMAZON FIRE STICK, ROKU, or APPLE TV, allow users to stream media directly to their television, avoiding the need for a media delivery company such as a cable company. Remote functioning is available with the use of a remote control unit which is independent from a control unit that remotely controls the functioning of the television.

While some of these devices or systems may be programmed to be controlled by a universal, single remote, this is not always the case. Even in situations where these devices are capable of being programmed to a universal remote control unit or the television remote control unit, such process can be problematic. Many of the current streaming devices use Wi-Fi (technology for wireless local area networking with devices based on IEEE 802.11 standards) or Blue Tooth technology (wireless technology standard for exchanging data over short distances). These technologies are generally not compatible with television remote controls units or universal remote control units which tend to function using infrared (IR) light.

### SUMMARY OF THE INVENTION

The present invention describes a system for securing two independent electronic device remote control units together. The system comprises one or more components, including an electronic device remote control and an interchangeable electronic device remote control securing member configured for attaching an auxiliary remote control device thereto. The system provides a mechanism to secure together at least two remote control devices that are not, or are not capable of, synchronizing each individual functionality into a single unit. In one embodiment, the system for securing multiple independent electronic device remote control units together comprises a first remote control unit configured to control one or more functions of an electronic device and configured to secure to an electronic device remote control securing member. The first remote control unit has a securing surface containing a plurality of securing members, each of the securing members are configured to engage one or more securing receiving elements associated with the electronic device remote control securing member. The electronic device remote control securing member comprising an electronic device remote control receiving surface having one or more securing receiving elements which, when engaged with the plurality of securing members, prevent separation of the first remote control unit and said electronic device remote control securing member along a plurality of axes. The electronic device remote control securing member comprising an auxiliary device securing component configured to engage and secure an auxiliary remote control device.

In another embodiment, the system for securing multiple independent electronic device remote control units together comprises an electronic device remote control securing member configured to secure to a first remote control unit which controls one or more functions of an electronic device; the electronic device remote control securing member comprising an electronic device remote control receiving surface and an auxiliary device securing component configured to receive and secure an auxiliary device to the electronic device remote control securing member.

Accordingly, it is an objective of the invention to provide a system for securing two independent electronic device remote control units together.

Other objectives and advantages of this invention will become apparent from the following description taken in conjunction with any accompanying drawings wherein are set forth, by way of illustration and example, certain embodiments of this invention. Any drawings contained herein constitute a part of this specification, include exemplary embodiments of the present invention, and illustrate various objects and features thereof.

### BRIEF DESCRIPTION OF THE FIGURES

FIG. 1 is a front perspective view of a system for securing two independent electronic device remote control units together;

FIG. 2 is a back perspective view of the system for securing two independent electronic device remote control units together;

FIG. 3 is a first side perspective view of an embodiment of an electronic device remote control;

FIG. 4 is a second side perspective view of the embodiment of an electronic device remote control;

FIG. 5 is a cross-sectional view of the electronic device remote control, illustrating the internal components that drive functionality;

FIG. 6 is a first side perspective view of an illustrative example of an electronic device remote control securing member;

FIG. 7 is a second side perspective view of the illustrative example of an auxiliary electronic device remote control securing member;

FIG. 8 is a perspective view of the interconnection of the first electronic device remote control unit with the auxiliary electronic device remote control securing member;

FIG. 9 illustrates the locking mechanism;

FIG. 10 is a front perspective view of the system for securing two independent electronic device remote control units together;

FIG. 11 is a back perspective view of the system for securing two independent electronic device remote control units together;

FIG. 12 is a perspective view of an illustrative example of an auxiliary electronic device remote control securing member;

FIG. 13 is an alternative view of an auxiliary electronic device remote control securing member;

FIG. 14 is an alternative view of an auxiliary electronic device remote control securing member;

FIG. 15 is an alternative view of an auxiliary electronic device remote control securing member;

FIG. 16 is a front perspective view of the system for securing two independent electronic device remote control units together;

FIG. 17 is a back perspective view of the system for securing two independent electronic device remote control units together as illustrated in FIG. 16;

FIG. 18 is a perspective view of an illustrative electronic device remote control securing member utilizing bands;

FIG. 19 is a perspective view of the electronic device remote control securing member utilizing bands with the bands removed;

FIG. 20 is an expanded view of a portion of the electronic device remote control securing member shown in FIG. 19; and

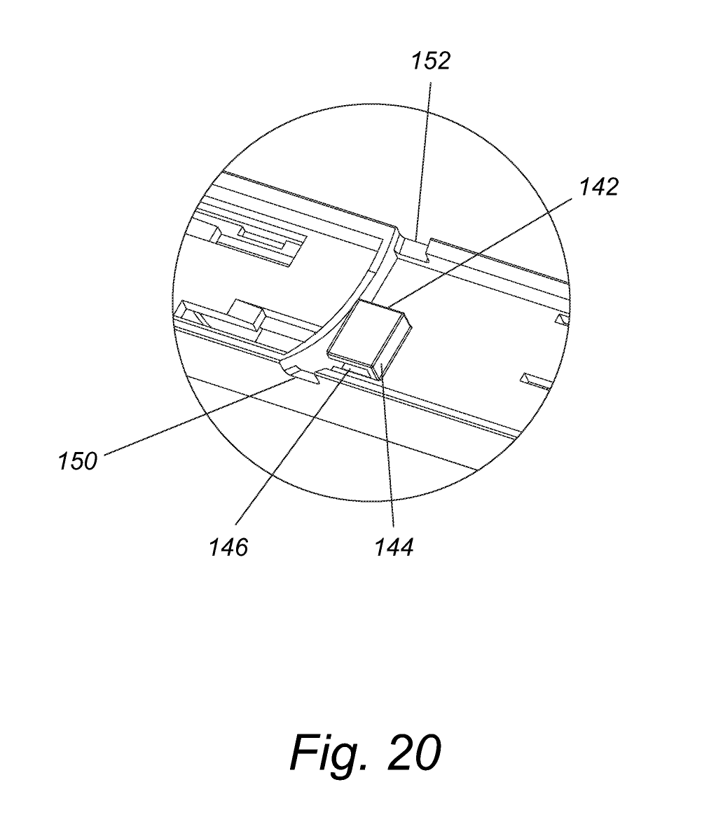

FIG. 21 is a perspective view of an illustrative electronic device remote control securing member.

### DETAILED DESCRIPTION OF THE INVENTION

While the present invention is susceptible of embodiment in various forms, there is shown in the drawings and will hereinafter be described a presently preferred, albeit not limiting, embodiment with the understanding that the present disclosure is to be considered an exemplification of the present invention and is not intended to limit the invention to the specific embodiments illustrated.

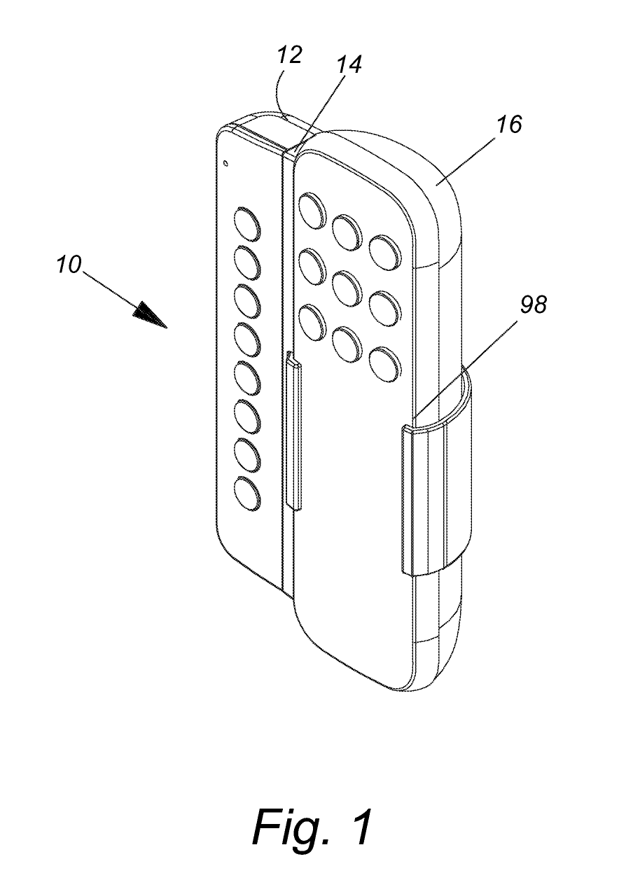

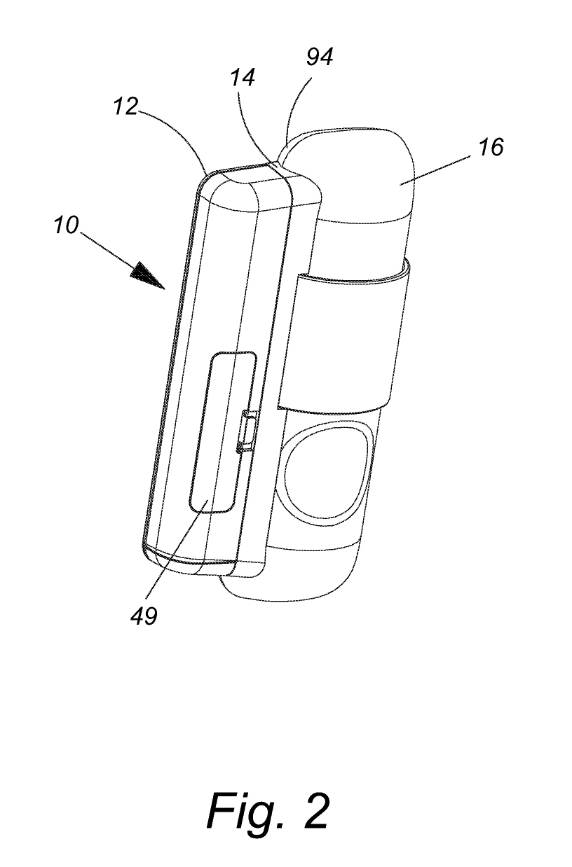

A system for securing two independent electronic device remote control units together, referred to generally as system 10, is illustrated in FIGS. 1 and 2. The system 10 comprises one or more components, including an electronic device remote control 12 and an interchangeable electronic device remote control securing member 14 configured for attaching an auxiliary remote control device 16 thereto. System 10 provides a mechanism to secure together at least two remote control devices that are not, or are not capable of, synchronizing each individual functionality into a single unit.

The electronic device remote control 12 is configured to control one or more electronic units, such as a television or DVD player, that could be synchronized into one functioning unit using a singe wireless communication mechanism, such as infrared. As used herein, the term “functioning unit” or “functioning” when referring to the electronic device remote control 12, or the auxiliary remote control 16, means that the particular unit works as intended. For example, if the electronic device remote control 12 is a functioning unit for a television, the device should be able to remotely control one or more features relating to the functions or capabilities of a television, such as changing channels, adjusting the volume, powering the television on or off, or other specialty type functions such as mute, pause, fast forward or reverse.

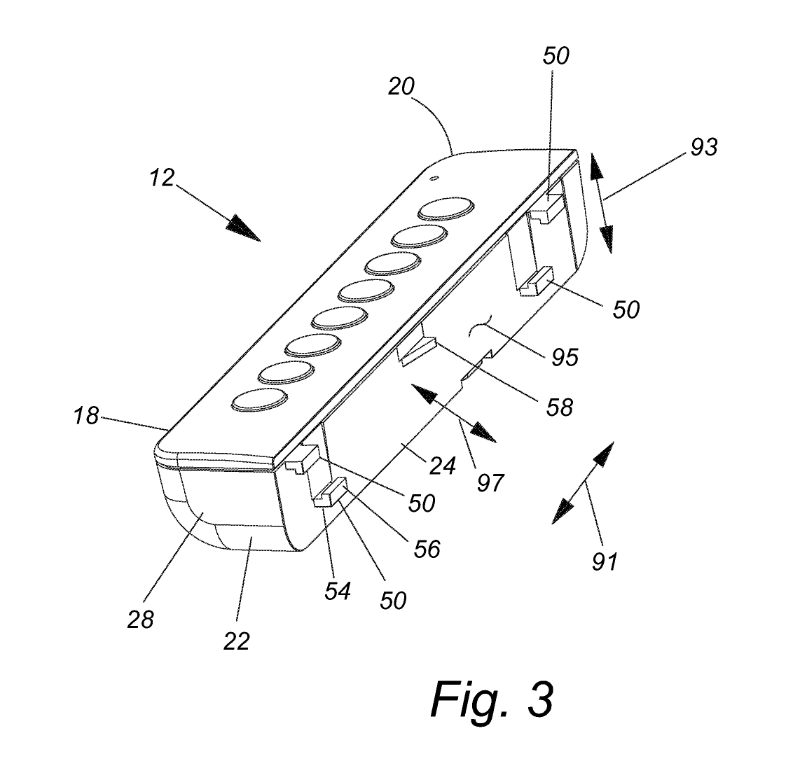

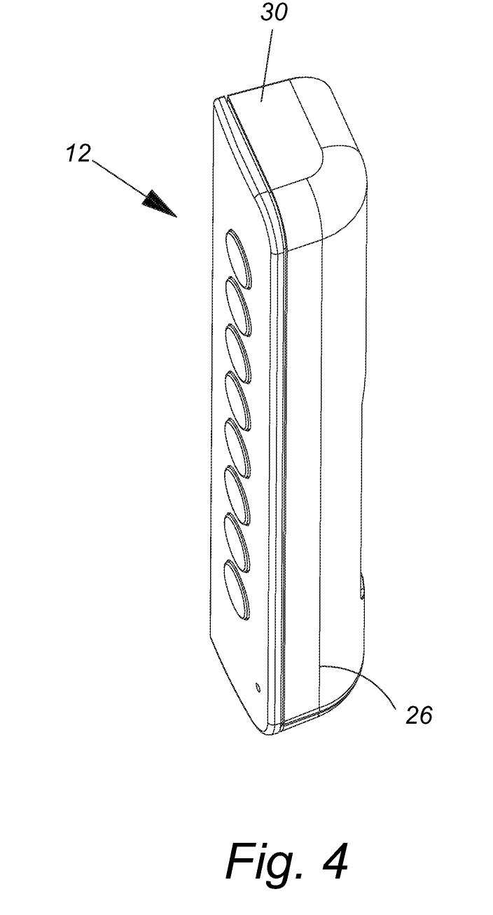

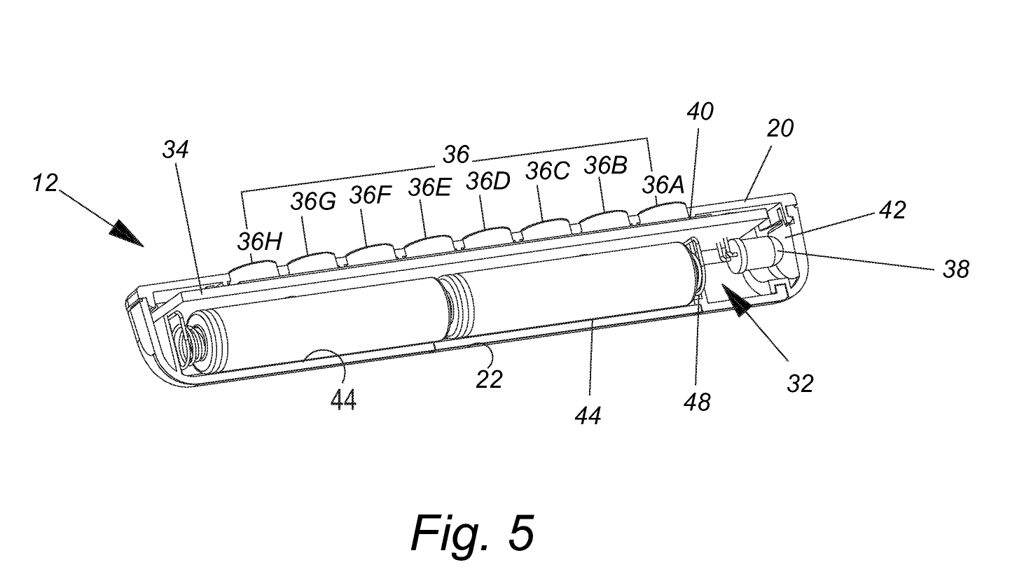

The electronic device remote control 12 comprises a main body 18 which houses one or more internal components that allow for the electronic device remote control 12 to function, see FIG. 3 and FIG. 4. The main body 18 comprises an upper shell 20 and a bottom shell 22. The bottom shell 22 contains a securing surface 24, a second, opposing surface 26 (see FIG. 4) and two opposing ends 28 and 30. The upper shell 20 and the bottom shell 22 are secured together to form an interior 32 (see FIG. 5). Positioned within the interior 32 are several components that drive the functionality of the electronic device remote control 12. A printed circuit board 34 containing the necessary electronic components, such as one or more of an integrated circuit or chip with etched in wires, resistors, capacitors, transistors, or resonators, to detect when a button 36 (referred to generally as 36) is pressed and translate the button pressed into a particular sequence. A light emitting diode (LED) 38 is located at one end of the circuit board 34. The LED 38 is designed to provide a signal, such as an infrared light, to the external device that it controls.

One or more buttons 36 are located on a button pad 40. The buttons 36 may be configured to power a device on/off 36A, control volume (louder 36B/softer 36C), control changing of channels (up 36D/down 36E), or may promote programming, 36F-36H. The infrared light is directed through the infrared (IR) window 42. One or more batteries 44, such as AAA alkaline batteries, connected to the cathode spring contact 46 and the anode contact 48 power the electronic device remote control 12. A battery door 49 (see FIG. 2) allows easy access to remove and replace the batteries 44.

The electronic device remote control 12 receives and/or secures to the interchangeable electronic device remote control securing member 14 at the bottom shell securing surface 24. The bottom shell securing surface 24 contains one or more securing members 50, each configured to engage securing member receiving element 52 (to be described later) associated with electronic device remote control securing member 14. The bottom shell securing surface securing members 50 are illustrated as having a generally L-shaped or hooked body, having a first portion 54 extending out and away from the bottom shell securing surface 24, and a second portion 56 extending out and way from the first portion 54, preferably at an angle; the second portion 56 being hooked to allow securing to a portion of the securing receiving elements 52, thereby preventing separation along at least one axis (upward/downward movement axis). A ramped tab 58 secures and maintains the interchangeable electronic device remote control securing member 14 locked in place, and prevents separation along a second axis. The ramped tab 58 further allows for removal of the interchangeable electronic device remote control securing member 14 as required.

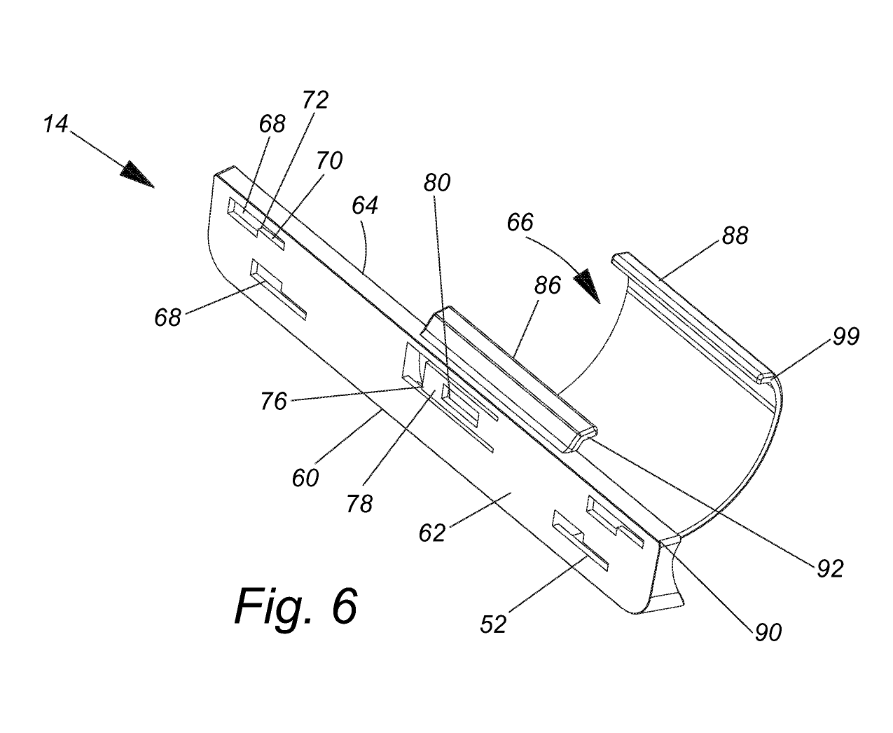

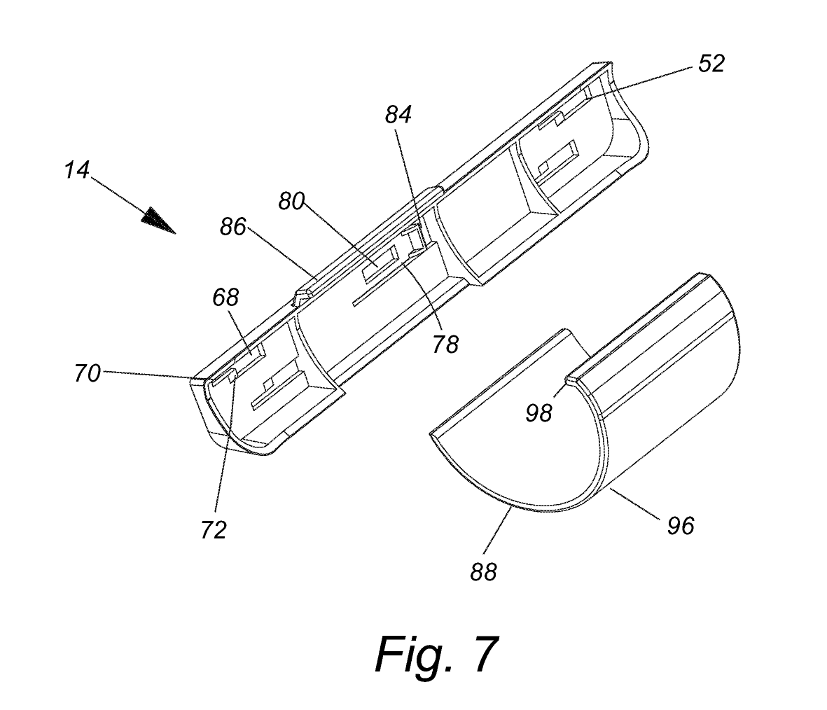

FIGS. 6 and 7 provide an illustrative example of the interchangeable electronic device remote control securing member 14. The interchangeable electronic device remote control securing member 14 comprising an elongated body 60 having a first receiving surface 62 and an opposing second surface 64. The interchangeable electronic device remote control securing member 14 further comprises an auxiliary device securing component 66. The elongated body is preferably shaped to mirror the size and/or the shape of the bottom shell securing surface 24. The electronic device remote control receiving surface 62 contains one or more interchangeable electronic device remote control securing member receiving elements or locks 52. Each one or more receiving elements 52 is sized, shaped, and orientated or positioned to receive and secure thereto the corresponding one or more bottom shell securing surface securing members 50.

The interchangeable electronic device remote control securing member receiving elements 52 are illustrated as keyhole slots having a first receiving cavity or channel 68 and a second receiving cavity or channel 70. The second receiving cavity 70 is continuous with the first receiving cavity 68. A stepped surface 72 helps guide an inserted portion of the bottom shell securing surface securing members 50 into the smaller diameter (as compared to the first receiving cavity 68) portion of the second receiving cavity 70, thereby locking in place. In use, a portion of the bottom shell securing surface securing members 50 is first inserted into the first receiving cavity 68 and then slid into the second receiving cavity 70.

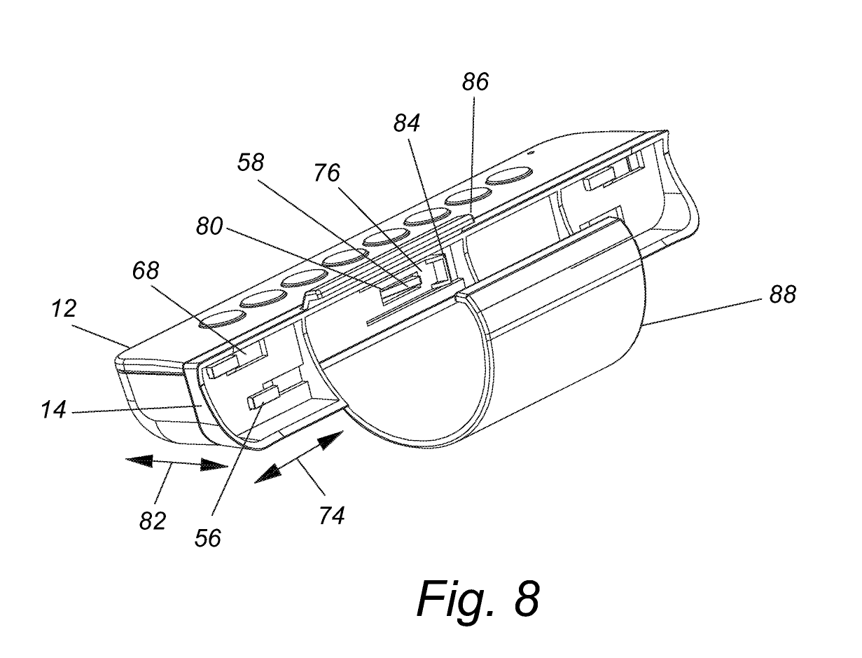

Once locked in place, see FIG. 8, the electronic device remote control 12 is prevented from side to side separation (see arrow 74, FIG. 8) from the interchangeable electronic device remote control securing member 14. The electronic device remote control receiving surface 62 may further comprise a locking tab 76, also referred to as a spring lock. The locking tab 76 comprises a flexible body 78 having an opening 80 sized and shaped to receive ramped tab 58. When the ramped tab 58 is placed and locked within the opening 80, the electronic device remote control 12 is further locked and secured to the interchangeable electronic device remote control securing member 14. This engagement prevents separation of the electronic device remote control 12 and the interchangeable electronic device remote control securing member 14 from lateral separation, see arrows 82, FIG. 8. Accordingly, this second engagement configuration prevents a directional separation of the electronic device remote control 12 and the interchangeable electronic device remote control securing member 14 that is different than that accomplished by the interaction of the bottom shell securing surface securing members 50 and the interchangeable electronic device remote control securing member receiving elements 52. To aid in separation, the locking tab 76 may contain a release pull tab 84, thus allowing for manipulation of the flexible body 78.

The interchangeable electronic device remote control securing member auxiliary device securing component 66 is configured to receive and secure at least portions of an auxiliary device, such as an auxiliary remote control 16. As illustrated in FIGS. 7 and 8, the auxiliary device securing component 66 comprises a first member, illustrated herein as a retaining clip 86, and a second member, illustrated herein as retaining clip arm 88. The retaining clip 86 extends outwardly, away from a surface 90 and contains a curved portion 92. The curved portion 92 allows for securing the retaining clip 86 around a portion of an inserted auxiliary remote control 16 along one of its surfaces 94 (see FIG. 2). The retaining clip arm 88 contains a curved body 96 extending outwardly and away from the interchangeable electronic device remote control securing member 14. The retaining clip arm 88 contains a curved body 96 with a hooked end 99 configured to engage a portion of the inserted auxiliary remote control 16 along a second surface 98 (see FIG. 1). The retaining clip arm 88 may be made of a flexible material, such as a flexible plastic, to allow the arm to flex or stretch over a portion of the auxiliary remote control 16 during the insertion step, snapping back to its original position once completely inserted. The retaining clip 86 may also be made of a flexible material to function in the same manner. The retaining clip 86 and retaining clip arm 88 create a secure connection between the electronic device remote control 12, interchangeable electronic device remote control securing member 14, and the auxiliary remote control device 16.

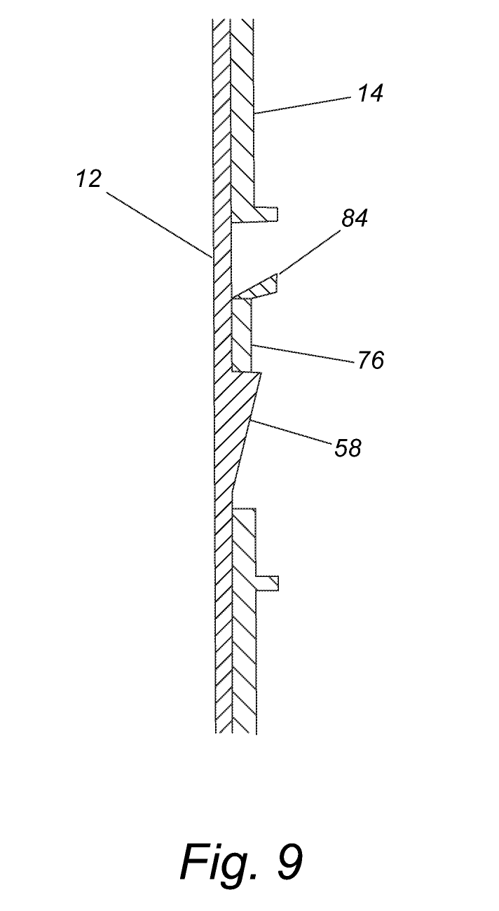

FIG. 9 illustrates a cross-section of some of the features that secure the electronic device remote control securing member 14 to the electronic device remote control 12. Once the one or more securing members 50 are inserted into the interchangeable electronic device remote control securing member receiving elements 52, the electronic device remote control securing member 14 can be slid parallel to the mating surface of the electronic device remote control 12. As the electronic device remote control securing member 14 is slid relative to the electronic device remote control 12, the locking tab 76 slides up the ramped tab 58 until it reaches the apex; at which point it returns to its natural position on the opposite side of the ramped tab 58. The electronic device remote control securing member 14 now remains in place until the electronic device remote control securing member 14 is pulled away from the electronic device remote control 12), thus locking the electronic device remote control securing member 14 to the electronic device remote control 12. To remove the electronic device remote control securing member 14 from the electronic device remote control 12, the ramped tab 58 must be pulled away from the electronic device remote control 12 enough to clear the apex of the ramped tab 58 and then slid in the direction down the ramp. Features such as a release pull tab 84 are attached to the locking tab 76 in order to aid in the removal process.

Once the electronic device remote control 12 and the electronic device remote control securing member 14 are secured together, the configuration, interaction, and inclusion of the securing components, i.e. one or more securing members 50, the ramped tab 58, the electronic device remote control securing member receiving elements 52, and the locking tab 76, interact to prevent separation along multiple axes. The plurality of axes include 1) side to side axis, defining separation or movement in a side to side manner, see arrows 91, FIG. 3; 2) up/down axis, defining separation or movement in an upward or downward manner, see arrows 93; or 3) away/towards axis, defining separation or movement in a direction that is away from or towards surface 95, see arrows 97.

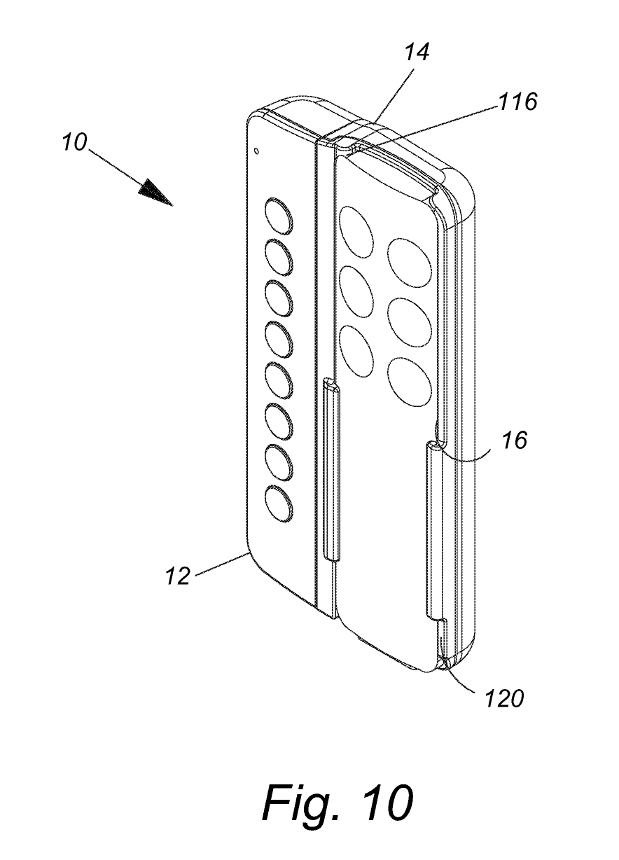

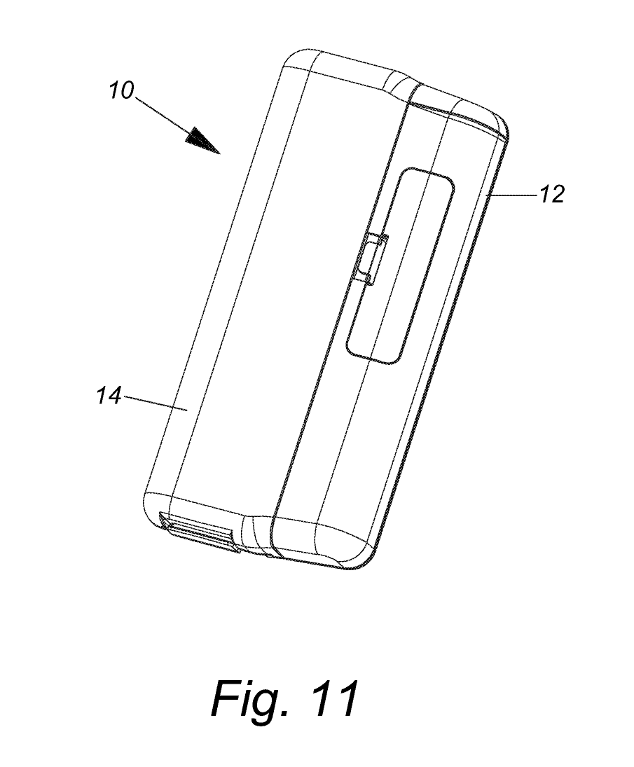

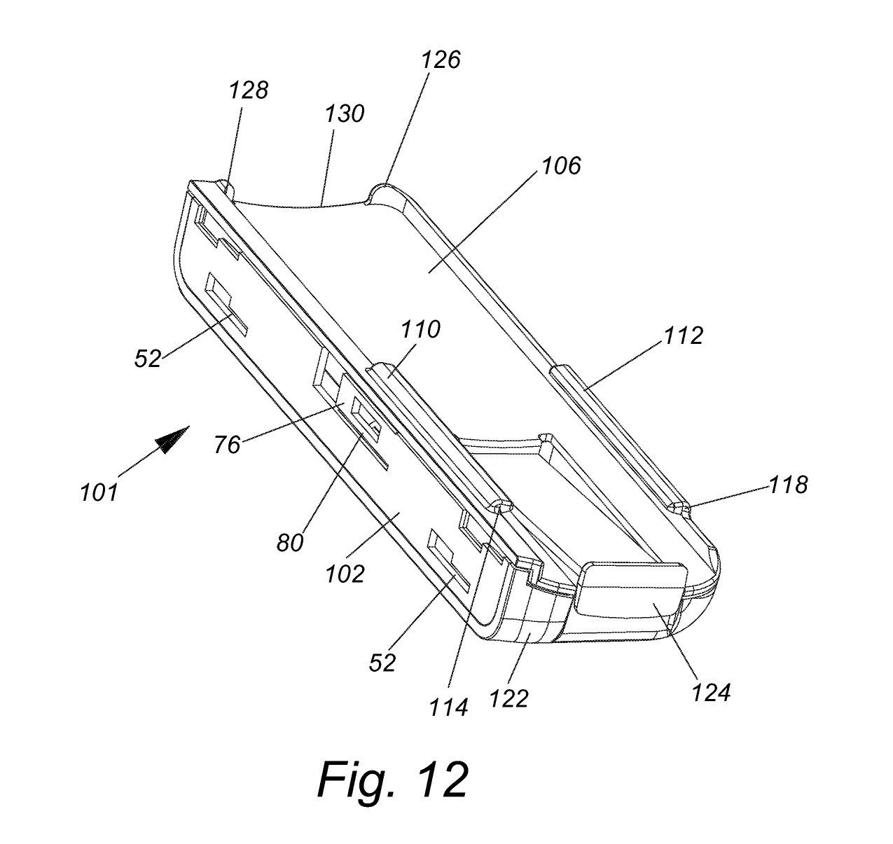

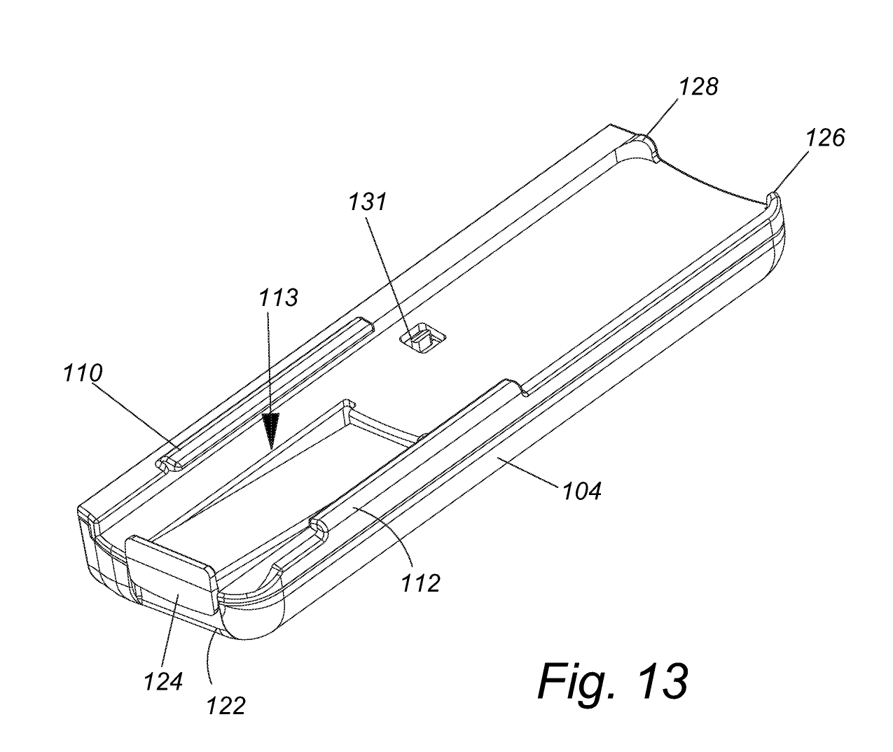

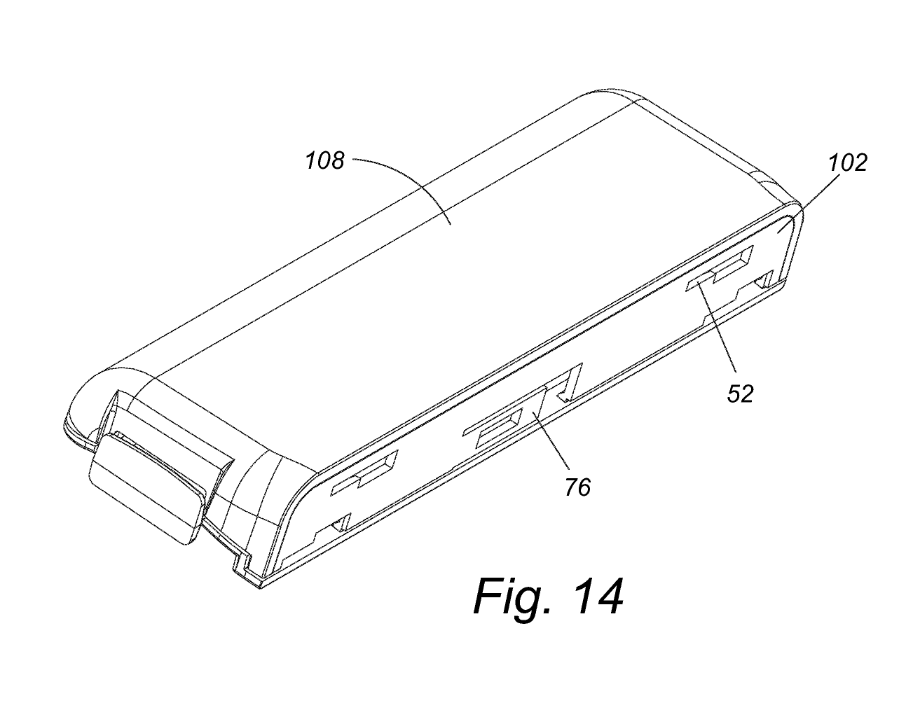

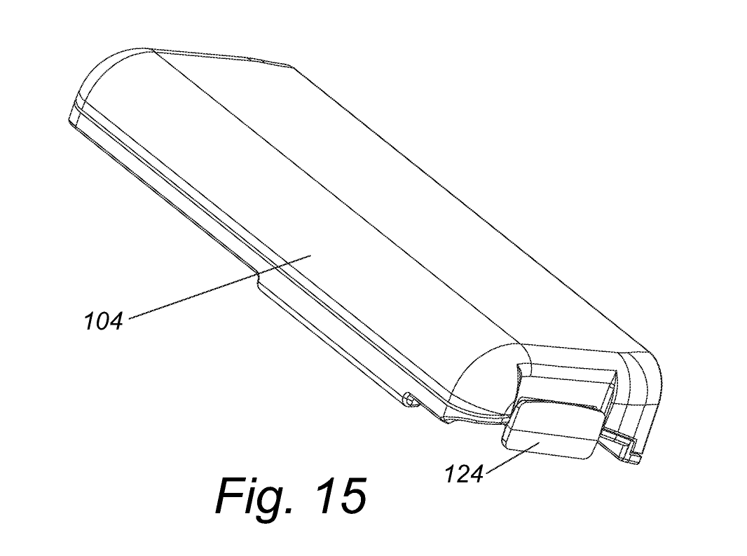

FIGS. 10-15 illustrate system 10 with an interchangeable electronic device remote control securing member 14 that utilizes a different embodiment of the auxiliary device securing component 66 for securing an auxiliary device thereto. Except where further described, the system 10 contains all the same components as previously described. As such, common features will be labeled with the same identifier, but not further described. The interchangeable electronic device remote control securing member 14 comprises an auxiliary device securing component or cradle 101 having two opposing side walls, a first electronic device remote control receiving wall 102 and an opposing second electronic device remote control receiving wall 104. The first electronic device remote control receiving wall 102 is configured to secure to a portion of the electronic device remote control 12. The first electronic device remote control receiving wall 102 contains one or more interchangeable electronic device remote control securing member receiving elements 52 and the locking tab 76.

The interchangeable electronic device remote control securing member 14 further contains an inner surface 106 sized and shaped to support an auxiliary device when inserted therein and an outer wall 108. A first rail 110 extending upwardly and having at least a portion extending away from wall 102, and a second rail 112 extending upwardly and having at least a portion extending away from wall 104, secure the auxiliary remote control 16 when inserted therein. The inner surface 106 and the rails 110 and 112 create a receiving channel 113 for receiving and supporting the auxiliary remote 16. The curved or angled portion 114 of first rail 110 is configured to engage a portion of the inserted auxiliary remote control 16 along a first surface 116, see FIG. 10. The curved or angled portion 118 of second rail 112 is configured to engage a portion of the inserted auxiliary remote control 16 along a second surface 120.

Positioned at a first end 122 of the cradle is an auxiliary remote retaining clip 124. The auxiliary remote retaining clip 124 is flexibly or movably attached to, or integrally formed to a portion of the inner surface 106. In use, the auxiliary remote 16 is slid into the receiving channel 113 until the sliding motion is restricted by end stops 126 and 128 at second end 130. When the auxiliary remote 16 engages the receiving channel 113, the auxiliary remote retaining clip 124 is deflected down towards the inner surface 106. When the auxiliary remote 16 is slid down toward the end stops 126 and 128, the ramped tab 58 (may also be referred to as a ramped locking tab 58) is free to return to its natural upward position, thereby securing the auxiliary remote 16 into the receiving channel 113 of the interchangeable electronic device remote control securing member 14. A release tab 131 engages or is attached (preferably along a back surface) to a portion of the locking tab 76. Sliding the release tab 131 to the right causes the locking tab 76 to bend or flex, thereby releasing or aiding in the release from the ramped tab 58.

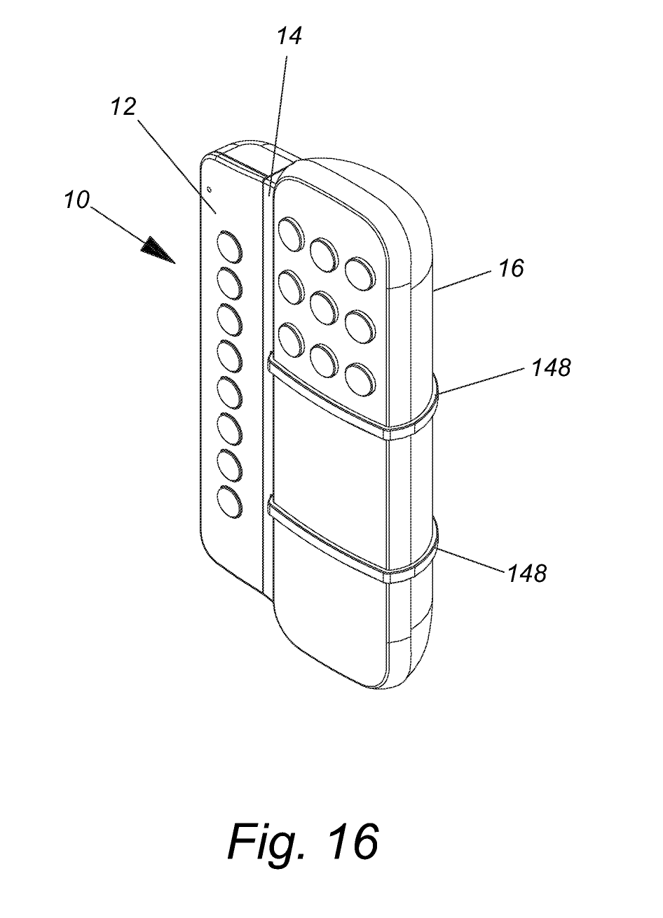

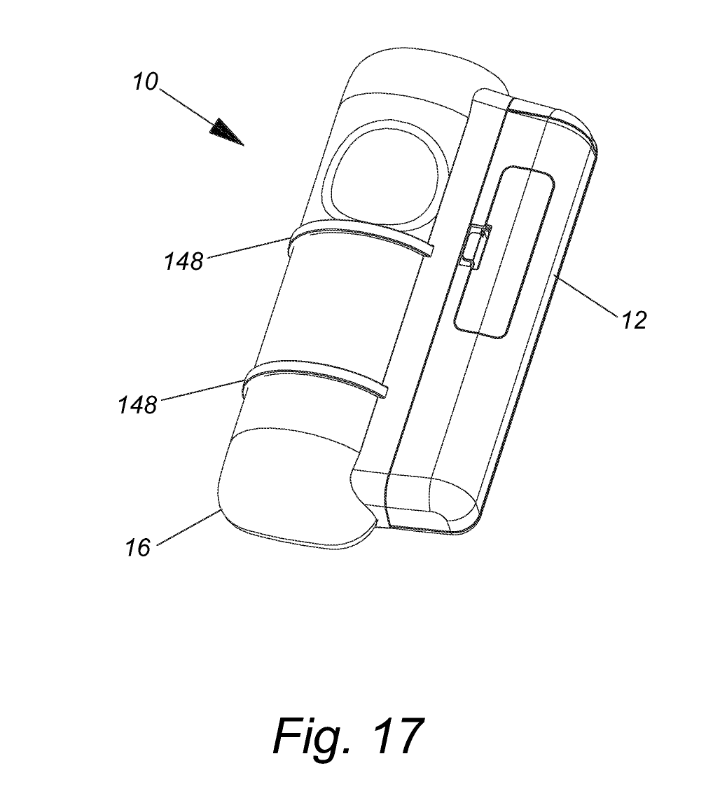

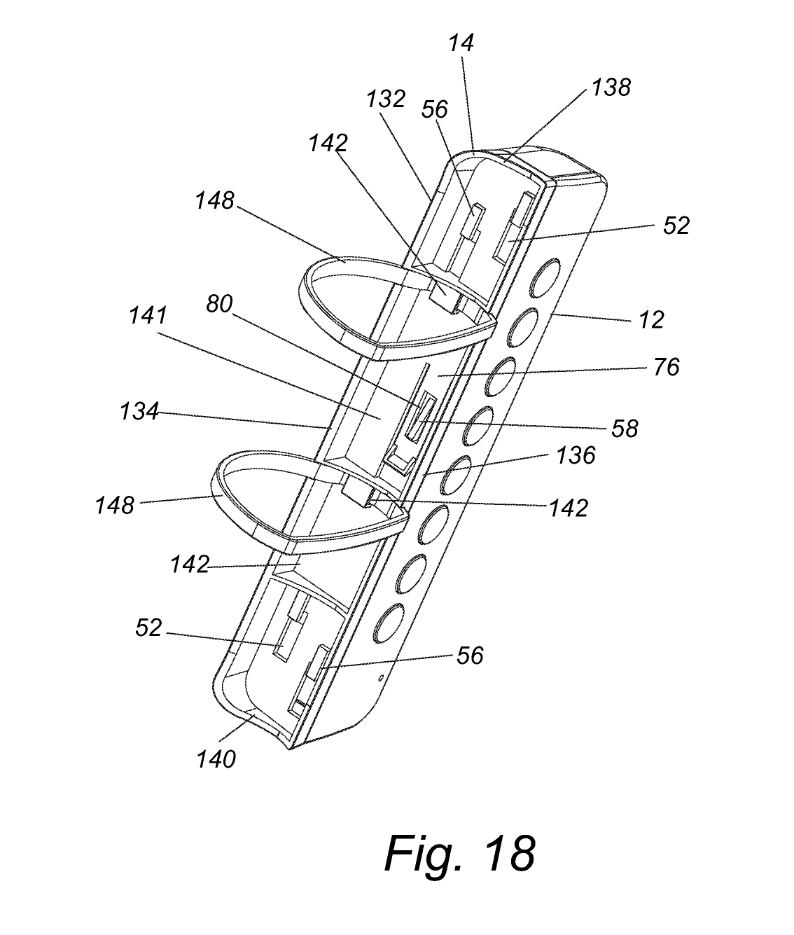

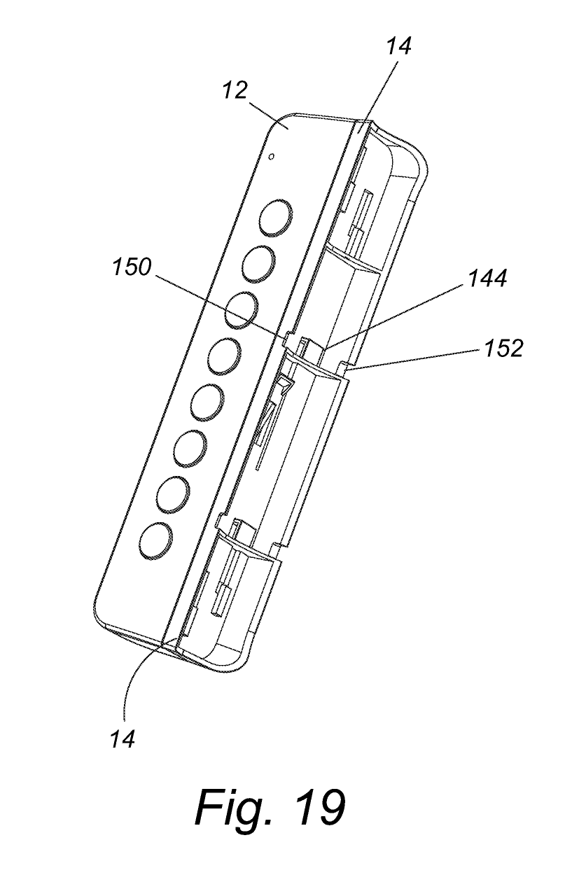

FIGS. 16-19 illustrate the system 10 with an interchangeable electronic device remote control securing member 14 that utilizes a different embodiment of the auxiliary device securing component 66 for securing an auxiliary device thereto. Except where further described, the system 10 contains all the same components as previously described. As such, common features will be labeled with the same identifier, but not further described. As illustrated in the figures, the interchangeable electronic device remote control securing member 14 comprises a body 132 having opposing side wells 134 and 136 separated by end walls 138 and 140. The body 132 comprises a surface or wall 141 that contains one or more interchangeable electronic device remote control securing member receiving members 52, as described above, and the locking tab 76. One or more securing band receiving members 142, shown having a u-shaped body with opening 146 secure auxiliary remote device bands 148 to the body 132. Cut-outs 150 and 152 in walls 134 and 136 are sized and shaped to receive at least a portion of the bands 148.

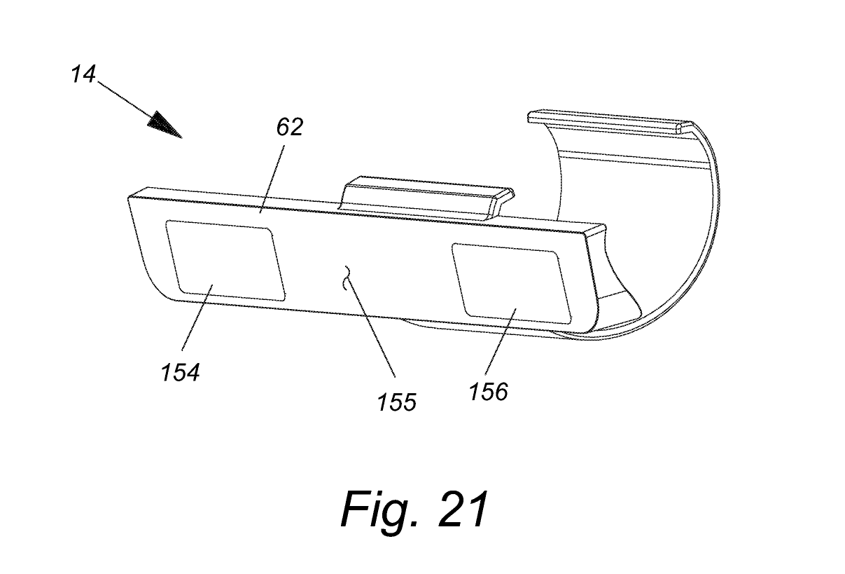

FIG. 21 illustrates the electronic device remote control receiving surface 62 of the interchangeable electronic device remote control securing member 14, in which the one or more interchangeable electronic device remote control securing member receiving elements 52 as described above and the locking tab 76 is replaced with a flat surface 155. To secure to the auxiliary remote control 16, one or more adhesion members 154 and 156 is used. The adhesion members 154 and 156 may be an adhesive material, such as a chemical composition, including a liquid adhesive, or may be one member of a loop and hook fastener, such as VELCRO. The adhesive material 158 may be a repositionable adhesive or putty, such as BLUE STICK adhesive, GLUE DOT Adhesives, SCOTCH adhesive dots, or SCOTCH removable mounting squares. The adhesive material may be covered by a protective sheet (not shown) which the user peels away prior to securing to the surface of the auxiliary remote device 16. Whatever material the adhesion member is made of, it must allow coupling, binding or securing to the auxiliary remote device 16. Alternatively, one or more portions of the auxiliary remote device 16 may contain adhesion members. Alternatively, the adhesive material 158 may also be a magnet or magnetic material to secure to corresponding magnets or magnetic materials associated with other components of the system 10.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A system for securing multiple independent electronic device remote control units together comprising:
a first remote control unit configured to control one or more functions of an electronic device and configured to secure to an electronic device remote control securing member; said first remote control unit having a securing surface containing a plurality of securing members, each said securing member configured to engage one or more securing receiving elements associated with said electronic device remote control securing member;
said electronic device remote control securing member comprising an electronic device remote control receiving surface having one or more securing receiving elements which, when engaged with said plurality of securing members, prevent separation of said first remote control unit and said electronic device remote control securing member along a plurality of axes, said electronic device remote control securing member comprising an auxiliary device securing component configured to engage and secure an auxiliary remote control device.

2. The system for securing multiple independent electronic device remote control units together according to claim 1 wherein separation of said first remote control unit and said electronic device remote control securing member when secured together is prevented along three axes.

3. The system for securing multiple independent electronic device remote control units together according to claim 1 wherein said auxiliary device securing component comprises a retaining clip or a retaining clip arm.

4. The system for securing multiple independent electronic device remote control units together according to claim 1 wherein said auxiliary device securing component comprises a cradle.

5. The system for securing multiple independent electronic device remote control units together according to claim 2 wherein said retaining clip arm is flexible.

6. The system for securing multiple independent electronic device remote control units together according to claim 1 wherein said plurality of first remote control unit securing members includes a main body having a first portion extending out and away from said first remote control unit having a securing surface, and a second portion extending out and way from said first portion.

7. The system for securing multiple independent electronic device remote control units together according to claim 6 wherein said plurality of first remote control unit securing members includes a ramped tab.

8. The system for securing multiple independent electronic device remote control units together according to claim 1 wherein said securing member receiving elements comprise a keyhole slot having a first receiving channel and a second receiving channel, said first receiving channel being a different size than said second receiving channel.

9. The system for securing multiple independent electronic device remote control units together according to claim 1 wherein at least one said securing member receiving element comprises a spring lock tab.

10. A system for securing multiple independent electronic device remote control units together comprising an electronic device remote control securing member configured to secure to a first remote control unit which controls one or more functions of an electronic device; said electronic device remote control securing member comprising an electronic device remote control receiving surface and an auxiliary device securing component configured to receive and secure an auxiliary device to said electronic device remote control securing member.

11. The system for securing multiple independent electronic device remote control units together according to claim 10, wherein said electronic device remote control receiving surface comprises a plurality of securing receiving elements configured to secure to said remote control unit in a manner which prevents separation along a plurality of axes.

12. The system for securing multiple independent electronic device remote control units together according to claim 10 further including a first remote control unit configured to control one or more functions of an electronic device.

13. The system for securing multiple independent electronic device remote control units together according to claim 12 wherein said first remote control unit comprises a plurality of securing members configured to engage said electronic device remote control securing members.

14. The system for securing multiple independent electronic device remote control units together according to claim 13 wherein said securing members include a main body having a first portion extending out and away from said first remote control unit having a securing surface, and a second portion extending out and way from said first portion.

15. The system for securing multiple independent electronic device remote control units together according to claim 13 wherein said first remote control unit securing member includes a ramped tab.

16. The system for securing multiple independent electronic device remote control units together according to claim 11 wherein said securing member receiving elements comprise a keyhole slot having a first receiving channel and a second receiving channel, said first receiving channel being a different size than said second receiving channel.

17. The system for securing multiple independent electronic device remote control units together according to claim 11 wherein at least one said securing member receiving element comprises a spring lock tab.

18. The system for securing multiple independent electronic device remote control units together according to claim 10 wherein said auxiliary device securing component comprises a retaining clip, a retaining clip arm, or a retaining member cradle.

19. The system for securing multiple independent electronic device remote control units together according to claim 1 wherein said wherein said auxiliary device securing component comprises at least one band.

20. The system for securing multiple independent electronic device remote control units together according to claim 10 wherein said auxiliary device securing component comprises at least one band.
